(19) United States
(12) Patent Application Publication
(10) Pub. No.: US 2026/0221640 A1
(43) Pub. Date: Jul. 30, 2026

(54) CIRCUIT TRANSMISSION STRUCTURE AND CIRCUIT BOARD

(71) Applicant: AIP Inc., New Taipei City (TW)

(72) Inventors: Chia-ho WU, Tainan City (TW); Cheng-yang LIU, Huzhou City (CN); Dong-hua NI, Huzhou City (CN); Qi-chao LI, Hangzhou City (CN); Guo-bing ZHOU, Huzhou City (CN)

(73) Assignee: AIP Inc., New Taipei City (TW)

(21) Appl. No.: 19/457,256

(22) Filed: Jan. 23, 2026

(30) Foreign Application Priority Data
Jan. 24, 2025 (TW) 114103654

(51) Int. Cl. H01P 3/08

(52) U.S. Cl. CPC H01P 3/081

(57) ABSTRACT

The disclosure provides a circuit transmission structure, including: a first microstrip line and a low-frequency or direct current signal source. The first microstrip line is arranged between two signal lines for transmitting high-frequency signals, wherein the edge of the first microstrip line has a sub-wavelength periodic structure. The low frequency or direct current signal source is connected to one end of the first microstrip line.

### RELATED APPLICATION(S)

This application claims the benefit of priority of Taiwanese Patent Application No. 114103654 filed on Jan. 24, 2025, the contents of which are incorporated by reference as if fully set forth herein in their entirety.

### FIELD AND BACKGROUND OF THE INVENTION

The disclosure relates to a circuit transmission structure, and more particularly, to a circuit transmission structure and a circuit board suitable for high frequency signal.

High-frequency circuit boards or high-frequency traces within circuit boards can suffer from severe crosstalk issues. When the signal frequency exceeds 5 GHZ, the traditional three-times-the-width trace design principle is no longer applicable. Even increasing the distance between two signal lines transmitting high-frequency signals to more than three times the width of that signal line cannot solve the crosstalk issue. As shown in FIG. 1, grounded isolation lines are used to isolate differential signal lines from other signal lines. When the wiring density on the circuit board is increased, making the distance between the differential signal lines on both sides less than three times the width of that signal line, the isolation effect of this isolation line is poor, and it affects the wiring configuration of other layers of a multi-layer circuit board, resulting in low trace utilization of the circuit board. Introducing a microstrip isolation line with a subwavelength periodic structure between two signal lines can solve the crosstalk issue, but the microstrip isolation line itself does not transmit any signal, so the utilization rate of the circuit board cannot be improved. Therefore, there is a need to solve the issues of crosstalk of high-frequency trace and low utilization of circuit board trace.

### SUMMARY OF THE INVENTION

In view of the aforementioned prior art, the present disclosure aims to provide a circuit transmission structure and circuit board that effectively solves the issues of crosstalk of high-frequency trace and low utilization of circuit board trace in the prior art.

To achieve at least one the above objectives, the present disclosure provides a circuit transmission structure including: a first microstrip line and a low-frequency or DC signal source. The first microstrip line is disposed between two signal lines for transmitting high-frequency signals, wherein an edge of the first microstrip line is provided with a subwavelength periodic structure. The low-frequency or DC signal source is connected to one end of the first microstrip line.

Optional, in one embodiment of the disclosure, the two signal lines are spaced at a distance less than or equal to three times a linewidth of one of the two signal lines.

Optional, in one embodiment of the disclosure, the circuit transmission structure further includes: a second microstrip line disposed between the two signal lines, wherein an edge of the second microstrip line is provided with a subwavelength periodic structure; and a second low-frequency or DC signal source connected to one end of the second microstrip line.

Optional, in one embodiment of the disclosure, the circuit transmission structure further includes: a third microstrip line disposed between the two signal lines, wherein an edge of the third microstrip line is provided with a subwavelength periodic structure; and a third low-frequency or DC signal source connected to one end of the third microstrip line.

Optional, in one embodiment of the disclosure, the circuit transmission structure further includes a load electrically connected to another end of the first microstrip line.

Optional, in one embodiment of the disclosure, the circuit transmission structure further includes a matching resistor electrically connected to the another end of the first microstrip line.

Optional, in one embodiment of the disclosure, the resistance value of the matching resistor is between 48.75Ω and 101.25Ω.

Optional, in one embodiment of the disclosure, the circuit transmission structure further includes a metal conductor electrically connected between the another end of the first microstrip line and a current return path.

Optional, in one embodiment of the disclosure, the another end of the first microstrip line is an open circuit.

Optional, in one embodiment of the disclosure, a period constant of the subwavelength periodic structure is less than dₘᵢₙ, where

$${d}_{min} = \frac{v {R}_{T}}{2} ,$$

v is a propagation rate of electromagnetic wave of the low-frequency or DC signal source in the first microstrip line, and R_{T} is a rise time of digital signal.

The present disclosure further provides circuit board, including: a substrate, a first microstrip line, and a low-frequency or DC signal source. The first microstrip line is disposed on the substrate and between two signal lines for transmitting high-frequency signals, wherein an edge of the first microstrip line is provided with a subwavelength periodic structure. The low-frequency or DC signal source is connected to one end of the first microstrip line, wherein a distance between the two signal lines is less than or equal to three times a linewidth of any one of the two signal lines.

Optional, in one embodiment of the disclosure, the circuit board further includes: a second microstrip line disposed on the substrate and between the two signal lines, wherein an edge of the second microstrip line is provided with a subwavelength periodic structure; and a second low-frequency or DC signal source connected to one end of the second microstrip line.

Optional, in one embodiment of the disclosure, the circuit board further includes: a third microstrip line disposed on the substrate and between the two signal lines, wherein an edge of the third microstrip line is provided with a subwavelength periodic structure; and a third low-frequency or DC signal source connected to one end of the third microstrip line.

Optional, in one embodiment of the disclosure, the circuit board further includes: a load electrically connected to another end of the first microstrip line.

Optional, in one embodiment of the disclosure, the circuit board further includes: a matching resistor electrically connected to the another end of the first microstrip line.

Optional, in one embodiment of the disclosure, the resistance value of the matching resistor is between 48.752 and 101.252.

Optional, in one embodiment of the disclosure, the circuit board further includes: a metal conductor electrically connected between the another end of the first microstrip line and a current return path.

Optional, in one embodiment of the disclosure, the another end of the first microstrip line is an open circuit.

Optional, in one embodiment of the disclosure, a period constant of the subwavelength periodic structure is less than dₘᵢₙ, where

$${d}_{min} = \frac{v {R}_{T}}{2} ,$$

v is a propagation rate of electromagnetic wave of the low-frequency or DC signal source in the first microstrip line, and R_{T} is a rise time of digital signal.

Compared to the prior art, the first microstrip line disclosed herein is used to transmit low-frequency or DC signals, and the edge of the first microstrip line is provided with the subwavelength periodic structure. This ensures that even if the two signal lines are separated by a distance less than or equal to three times the linewidth of any one of the two signal lines, there will not be significant crosstalk, and the transmission of low-frequency or DC signals on the first microstrip line will not be affected. This improves the utilization rate of traces on the circuit board and avoids the issues in the prior art.

### BRIEF DESCRIPTION OF THE SEVERAL VIEWS OF THE DRAWING(S)

FIG. 1 shows a three-dimensional schematic diagram of a conventional circuit transmission structure on a circuit board;

FIG. 2A shows two subwavelength periodic microstrip lines inserted between two pairs of differential lines for signal transmission;

FIG. 2B shows two smooth conventional microstrip lines inserted between two pairs of differential lines for signal transmission;

FIG. 2C shows the relationship between transmission coefficient Sss56 and frequency of FIGS. 2A and 2B;

FIG. 3A shows a schematic diagram of structure of conventional circuit transmission structure T1;

FIG. 3B shows a schematic diagram of a conventional circuit transmission structure T2;

FIG. 3C shows a schematic diagram of a circuit transmission structure of an embodiment of the disclosure;

FIG. 3D shows variation of the transmission coefficient S21 as a function of frequency of the circuit transmission structures in FIGS. 3A to 3C;

FIG. 3E shows variation of the parameter S41 with frequency of the circuit transmission structures in FIGS. 3A to 3C;

FIG. 4A shows a circuit transmission structure of an embodiment of the disclosure.

FIG. 4B shows a three-dimensional schematic diagram of a circuit transmission structure according to an embodiment of the disclosure;

FIG. 4C shows a three-dimensional schematic diagram of a circuit transmission structure according to an embodiment of the disclosure;

FIG. 4D shows the variation of parameter Sdd41 with signal frequency of the circuit transmission structure of FIGS. 4A to 4C;

FIG. 5A shows a schematic diagram of a circuit transmission structure according to an embodiment of the disclosure;

FIG. 5B shows a schematic diagram of a circuit transmission structure according to an embodiment of the disclosure.

FIG. 5C shows a schematic diagram of a circuit transmission structure of an embodiment of the disclosure;

FIG. 5D shows a schematic diagram of a circuit transmission structure of an embodiment of the disclosure;

FIG. 6A shows a schematic diagram of a circuit transmission structure of an embodiment of the disclosure;

FIG. 6B shows a schematic diagram of a circuit transmission structure of an embodiment of the disclosure;

FIG. 7 shows a partial three-dimensional schematic diagram of a circuit board of one embodiment of the disclosure.

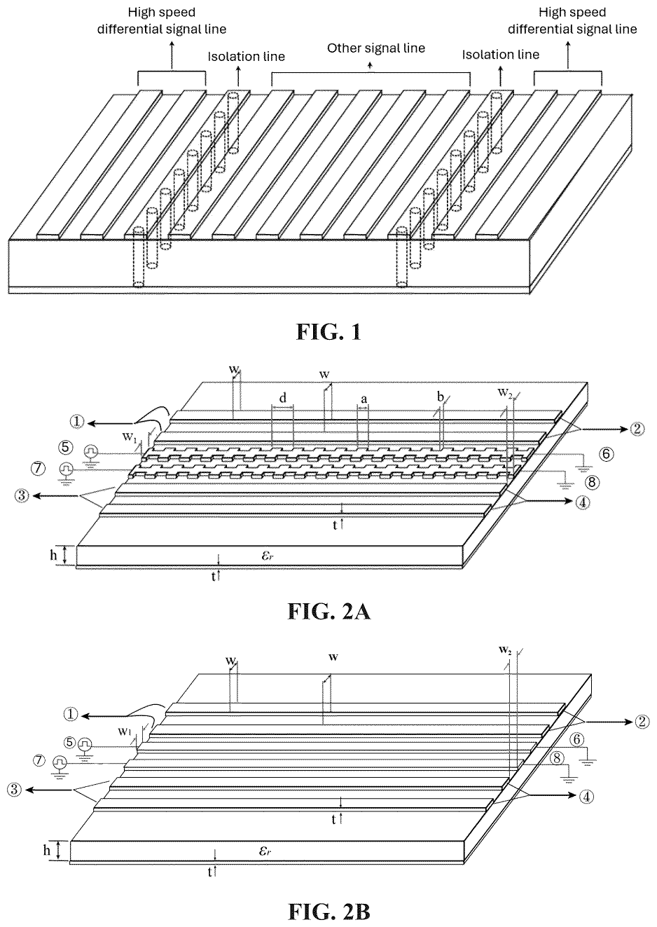

### REFERENCE NUMERALS DESCRIPTION

1, 2, 3, 4, 5, 6, 7, 8: terminal; 10: first microstrip line; 100, 101, 102, 103, 104, 110, 200, 210, 300, 310: circuit transmission structure; 20: second microstrip line; 30: third microstrip line; 40: dielectric plate; 400: circuit board; 41: substrate; 50: metal layer; a: groove width; b: Groove depth; d: lattice constant; h, t: thickness; H: high-frequency signal; H1, H1′, H2, H2′: signal line; LD: load; L1: first low-frequency or DC signal source; L2: second low-frequency or DC signal source; L3: third low-frequency or DC signal source; GM: metal conductor; GV: grounding isolation wire with via; R: matching resistance; Rs: surface resistance; SPM: subwavelength periodic structure; T1, T2: traditional circuit transmission structure; εᵣ: Dielectric constant; w: line width; w₁: width; w₂: distance.

### DESCRIPTION OF SPECIFIC EMBODIMENTS OF THE INVENTION

To make the above and other objects, features, and advantages of this disclosure more apparent, preferred embodiments of this disclosure will be described in detail below with reference to the drawings. Furthermore, in the drawings, structurally similar units are represented by the same reference numerals.

A microstrip isolation line with a subwavelength periodic structure is introduced between two signal lines. While this solves the crosstalk issue, the microstrip isolation line in the prior art itself does not transmit any signal, thus the trace utilization of the circuit board cannot be improved. Therefore, there is a need to solve the aforementioned issues of crosstalk in high-frequency trace and low utilization of circuit board trace. To transmit signals on subwavelength periodic microstrip isolated line, current techniques lack prior research exploring the crosstalk issues caused by high-speed signal lines to the microstrip isolated line and the impact of the subwavelength periodic structure on the signal integrity of the microstrip isolated line itself. To improve circuit board trace utilization, there is a need to research isolated line that allows the spacing between high-speed signal lines to be less than three times the line width to increase trace density. Simultaneously, the isolated line, positioned between high-speed signal lines, can still transmit signals to further increase trace density, achieving signal isolation or effectively reducing crosstalk without affecting the signal transmission of the isolated trace itself.

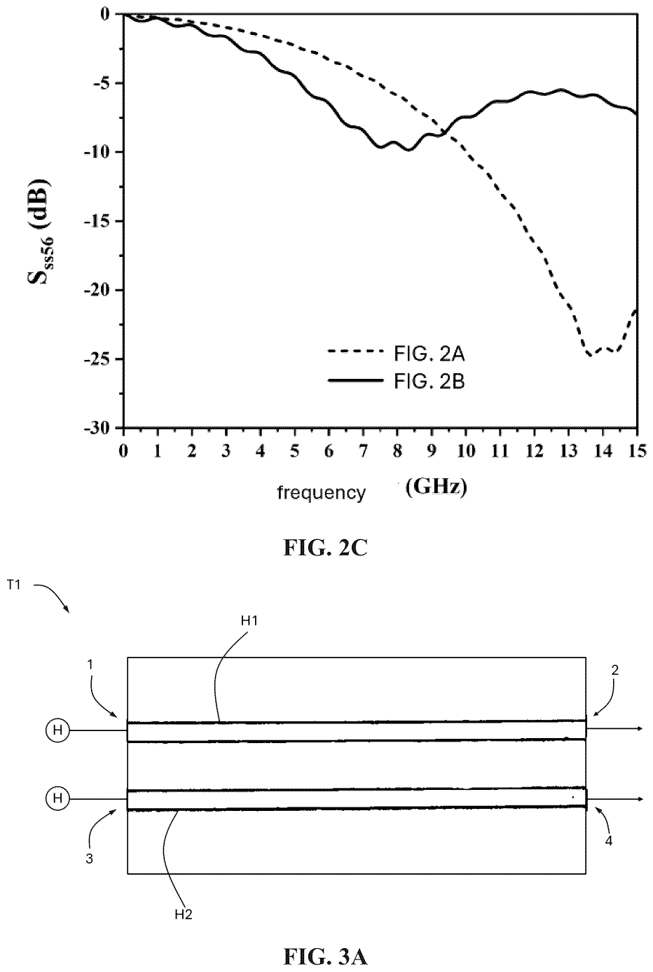

Referring to FIGS. 2A, 2B, and 2C, FIG. 2A illustrates two subwavelength periodic microstrip lines disposed between two pairs of differential lines to transmit signals. FIG. 2B, as a contrast set, illustrates two smooth conventional microstrip lines disposed between two pairs of differential lines to transmit signals. FIG. 2C illustrates the transmission coefficient Sₛₛ₅₆ as a function of frequency of FIGS. 2A and 2B. That is, the ratio of the signal strength at terminal 5 to the signal strength at terminal 6, representing the transmission capability of the signal on the isolated line from the near end terminal 5 to the far end terminal 6. A higher transmission coefficient Sₛₛ₅₆ is generally better; the ideal value is 1. FIG. 2C uses logarithmic representation, where log 1 equals 0. FIGS. 2A, 2B, and 2C are examples of differential lines used as signal lines for transmitting high-frequency signals. Generally speaking, signals with frequencies greater than 100 MHz can be considered high-frequency signals. As shown in FIG. 2C, when two subwavelength periodic microstrip lines are placed between two pairs of differential lines to transmit signals, the transmission efficiency of the subwavelength periodic microstrip lines decreases as the signal frequency increases, approaching-10 dB around 7 GHz. With further frequency increases, the transmission coefficient Sₛₛ₅₆ of the periodic microstrip line decreases even faster, reaching-24.74 dB at 13.65 GHz. Conversely, the transmission coefficient Sₛₛ₅₆ of traditional microstrip lines increases rapidly after 7 GHz, which is actually beneficial for high-frequency signal transmission. Based on this observation, it appears that using subwavelength periodic microstrip lines as isolation lines is unsuitable for transmitting high-frequency signals. While traditional smooth microstrip lines are advantageous for high-frequency signal transmission, they lack signal isolation capabilities. Therefore, simultaneously addressing both reducing crosstalk of high-frequency trace and enlarging utilization of low circuit board trace remains a challenge.

To address the issues of the prior art, the present disclosure aims to provide a circuit transmission structure and circuit board that effectively solves both crosstalk of high-frequency trace and low utilization of circuit board trace in the prior art.

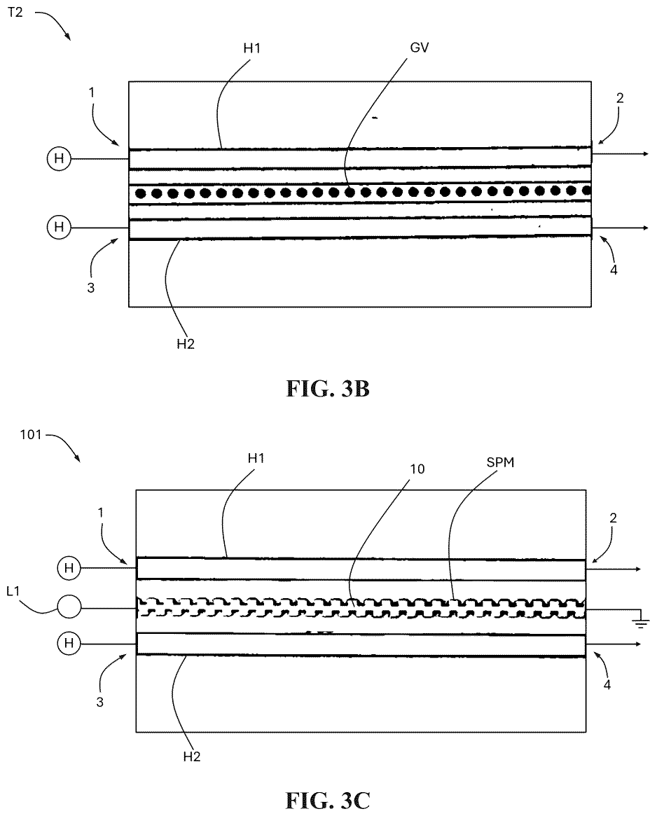

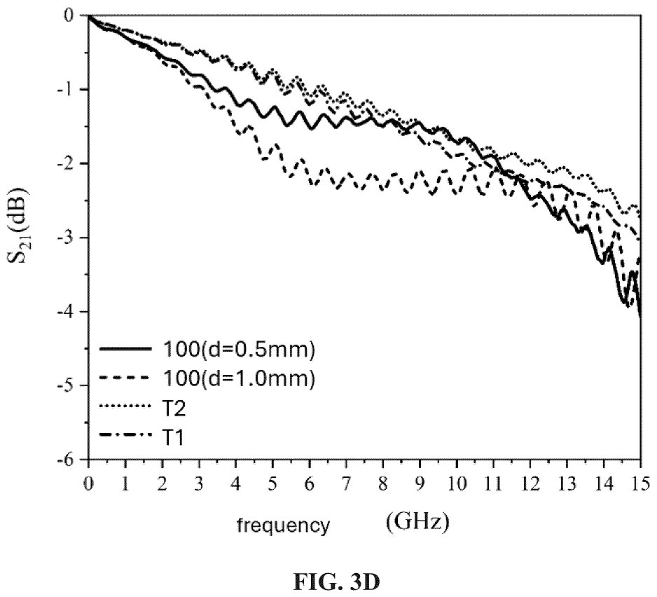

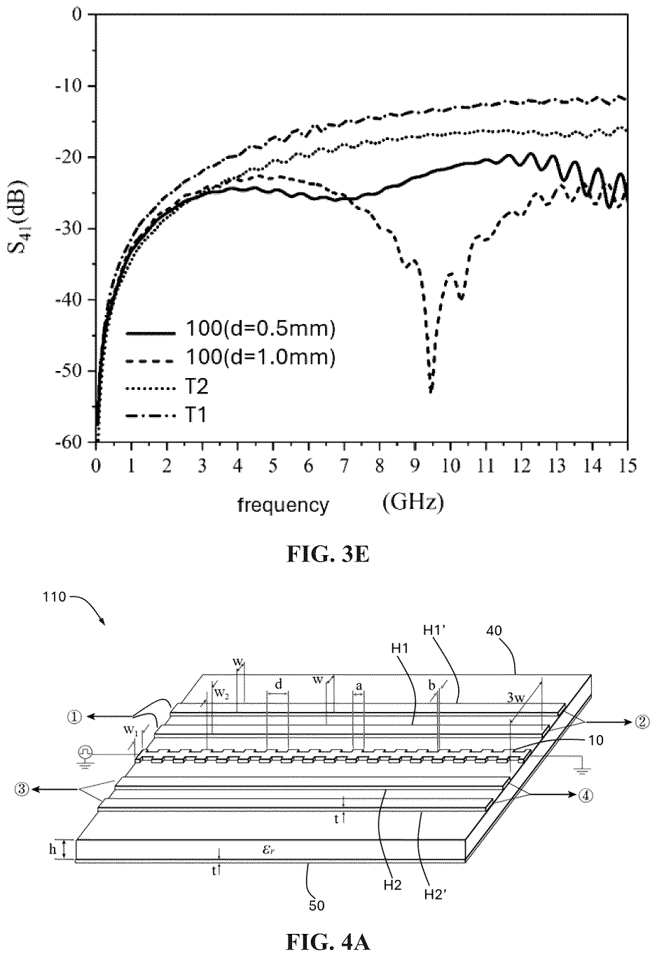

To achieve the above objective, as shown in FIG. 3C, the present disclosure provides a circuit transmission structure 100, including: a first microstrip line 10 and a low-frequency or DC signal source L1. The first microstrip line 10 is disposed between two signal lines H1 and H2 for transmitting a high-frequency signal H, wherein an edge of the first microstrip line 10 is provided with a subwavelength periodic structure SPM. The low-frequency or DC signal source L1 is connected to one end of the first microstrip line 10.

In detail, FIG. 3A illustrates a traditional circuit transmission structure T1 consisting of two high-speed signal lines H1 and H2 following a three-times-the-width rule. FIG. 3B illustrates a traditional circuit transmission structure T2 with a conventional hole-punched grounding isolation wire GV between the two high-speed signal lines H1 and H2. FIG. 3D illustrates the variation of the transmission coefficient S₂₁ as a function of frequency of the circuit transmission structures in FIGS. 3A to 3C. FIG. 3E illustrates the variation of the parameter S₄₁ as a function of frequency of the circuit transmission structures in FIGS. 3A to 3C. The transmission coefficient S₂₁ is the ratio of the signal strength at terminal 2 to the signal strength at terminal 1, representing the transmission capability of the signal on the high-speed signal line H1 from the near end terminal 1 to the far end terminal 2. A higher transmission coefficient S₂₁ is generally better; the ideal value is 1. FIG. 3D uses logarithmic representation, where log 1 equals 0. Parameter S₄₁, the ratio of signal strength at terminal 4 to signal strength at terminal 1, represents the proportion of signal transmitted from near end terminal 1 on high-speed signal line H1 to far end terminal 4 on high-speed signal line H2, i.e., crosstalk. A smaller parameter S₄₁ is generally better. As shown in FIG. 3D, although the transmission coefficient S₂₁ of the circuit transmission structure 100 in this embodiment is slightly lower than that of the conventional transmission structures T1 and T2, FIG. 3E shows that the parameter S₄₁ of the circuit transmission structure 100 in this embodiment is much lower than that of the conventional transmission structures T1 and T2, indicating significantly lower crosstalk. This is especially evident at high frequencies. In some embodiments, the high-speed signal lines H1 and H2 are, for example, signal lines transmitting signal frequencies greater than 100 MHz. In some embodiments, the low-frequency or DC signal source L1 is, for example, a DC signal, a signal with a signal frequency lower than 6 GHz, or a step signal with a rise time of rising edge less than 0.1 ns.

In detail, referring again to FIG. 2C, it can be seen that when signal frequencies below 9.5 GHZ, the subwavelength periodic microstrip line of FIG. 2A has better transmission efficiency. Furthermore, when signal frequencies below 6 GHz, the transmission coefficient Sₛₛ₅₆ of the subwavelength periodic microstrip line of FIG. 2A is greater than −3 dB, and its signal loss is acceptable. Circuit boards are not entirely composed of high-speed signal lines; they also include some lower-speed signal lines. Therefore, if lower-frequency lines are positioned between high-speed signal lines, and a subwavelength periodic structure is used at the edges of these low-frequency lines, crosstalk between high-speed signal lines can be reduced without affecting the signal integrity of the low-frequency signal lines. In detail, referring to FIG. 3C, for example, the signal frequency of the low-frequency or DC signal source L1 (providing clock, DC power, or addressing signals, etc.) connected to one end of the first microstrip line 10 can be configured to be below 6 GHz. This simultaneously reduces crosstalk between high-speed signal lines H1 and H2 without affecting the signal integrity of the first microstrip line 10. Therefore, more lines can be provided onto the same circuit board area without interfering with each other, improving the line utilization rate of the circuit board. In some embodiments, when the low-frequency or DC signal source L1 transmits a step signal on the first microstrip line 10, the signal integrity can be maintained if the rise time of the rising edge of the step signal is less than 0.1 ns.

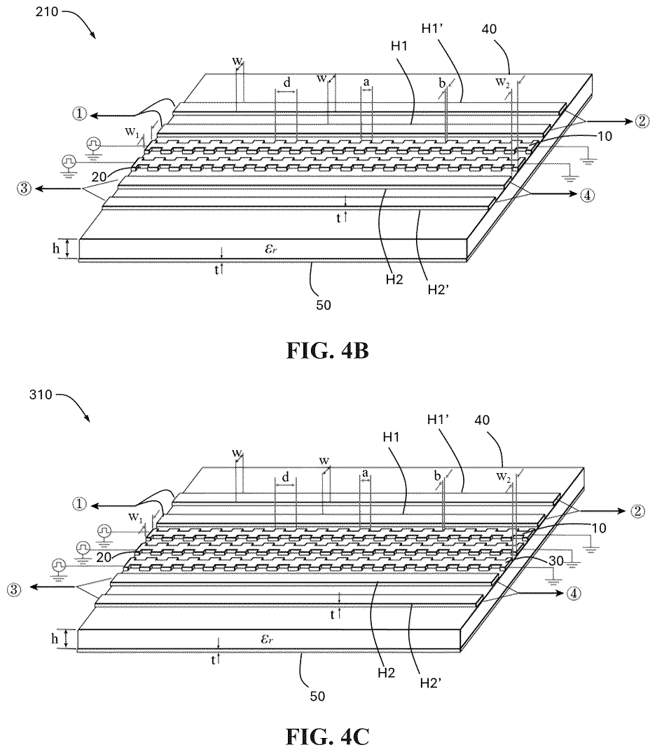

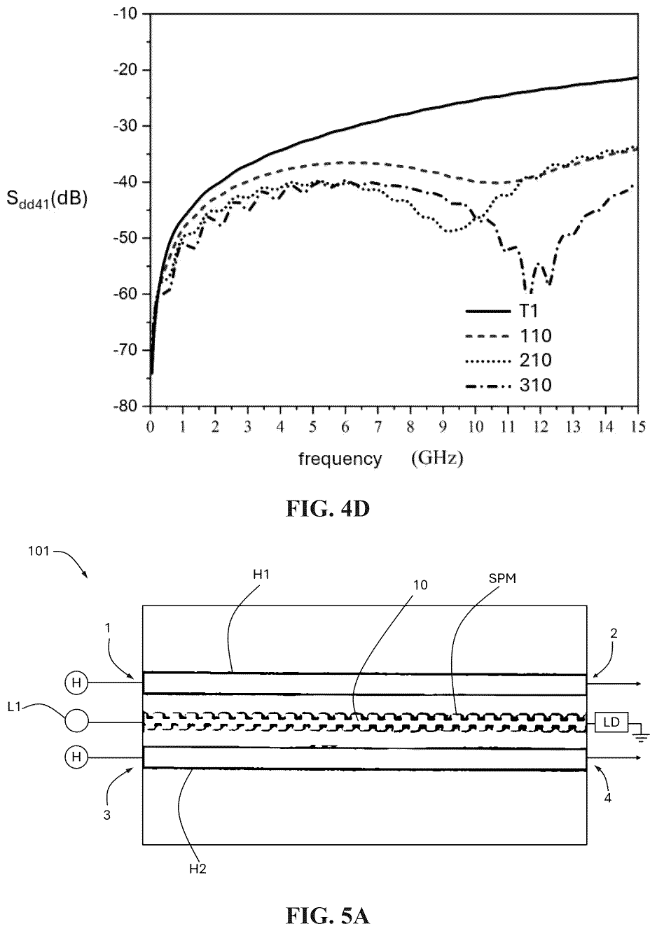

In one embodiment of this disclosure, the distance between the two signal lines H1 and H2 is less than or equal to three times the linewidth of the signal lines H1 or H2. In detail, please refer to FIG. 4A, which shows a three-dimensional schematic diagram of the circuit transmission structure of an embodiment of the disclosure. The dimensions indicated therein also apply to other FIGS., so FIG. 4A is mainly used for explanation. The distance between signal lines H1 and H2 is 3w. The linewidth of signal lines H1 or H2 is ω. The distance between signal line H1 or signal line H2 and the first microstrip line 10 is w₂, the width is w₁, the lattice constant is d, the groove depth is b, the groove width is a=0.5d, the thickness of the dielectric plate 40 is h, the dielectric constant is εᵣ, and the thickness of the metal layer 50 is t. Furthermore, signal lines H1 and H1′ form a differential pair, and signal lines H2 and H2′ form another differential pair.

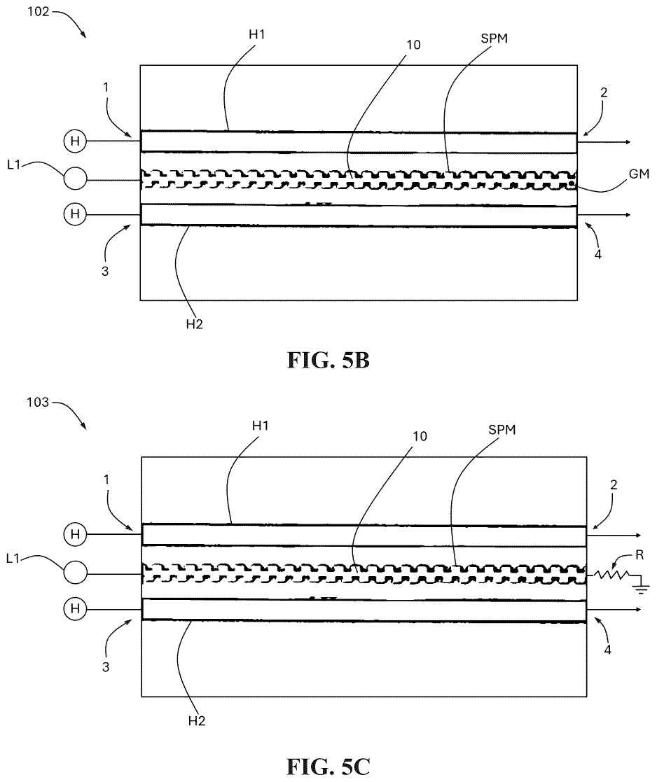

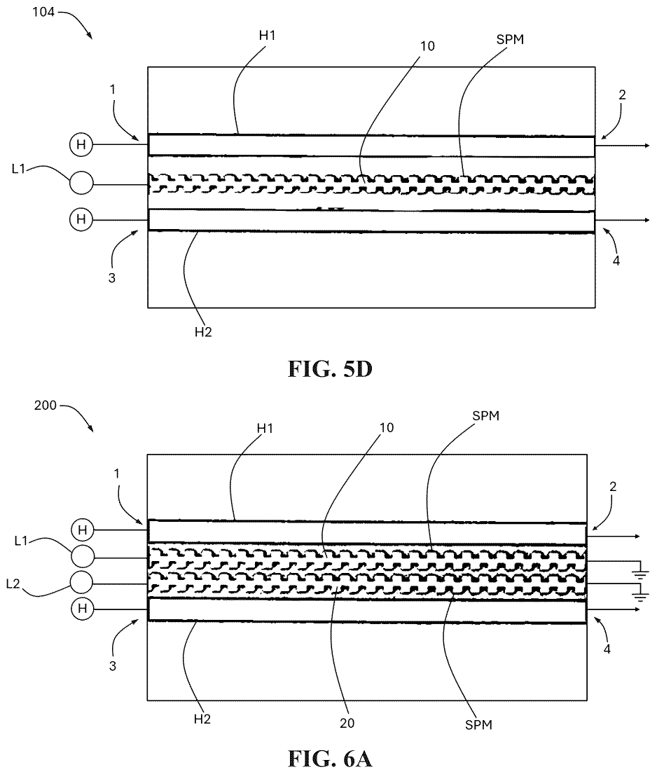

Please refer to FIGS. 5A to 5D, which illustrate schematic diagrams of circuit transmission structures according to different embodiments of the disclosure. One embodiment of the disclosure further includes a load LD in circuit transmission structure 101, electrically connected to the other end of the first microstrip line 10. The circuit transmission structure 102 further includes a metal conductor GM, electrically connected to the other end of the first microstrip line 10 and the current return path (i.e., metal layer 50 in FIG. 4A). The circuit transmission structure 103 further includes a matching resistor R, electrically connected to the other end of the first microstrip line 10. Or the other end of the first microstrip line 10 in circuit transmission structure 104 is an open circuit.

In one embodiment of this disclosure, the resistance value of the matching resistor is between 48.75Ω and 101.25Ω. Considering the structural dimensions of the first microstrip line 10 disclosed herein, calculations show that a 75Ω resistor is chosen to connect the first microstrip line 10 in the low-frequency band, which provides good absorption of electromagnetic waves. Experiments revealed that an impedance 75Ω plus or minus variation of 35% is acceptable, i.e., between 48.7502 and 101.2502.

In one embodiment of this disclosure, the period constant of the subwavelength periodic structure is less than dₘᵢₙ, where

$${d}_{min} = \frac{v {R}_{T}}{2} , \qquad ( Equation 1 )$$

v is the propagation velocity in the microstrip line of the electromagnetic wave from the signal source, and R_{T} is the rise time of the digital signal. In detail, dₘᵢₙ is the smallest lattice constant that can be resolved by a digital signal with a rise time of R_{T}. If the distance an electromagnetic wave travels during its rise time is greater than twice the lattice constant, the reflected wave will be covered by the rising edge, making it impossible to distinguish the impedance changes between two adjacent grooves. Periodic microstrip lines that satisfy this condition for transmitting low-frequency signals can more effectively reduce interactions with adjacent microstrip lines, thereby suppressing far-end crosstalk. Furthermore, for digital signals, if the lattice constant d of a subwavelength periodic microstrip line is less than dₘᵢₙ, the digital signal cannot distinguish the continuously distributed grooves in the periodic structure and can be considered as a uniform microstrip line. These periodic microstrip lines, equivalent to uniform microstrip lines, can effectively control the characteristic impedance.

Considering the measure of actual circuit structure, we chose the RO4003 circuit board. The dielectric substrate has a thickness h of 0.508 mm, a dielectric constant εᵣ of 3.37, a metal layer thickness t of 0.0175 mm, and a tangent loss tan δ=0.0027. To satisfy the subwavelength constraint of lattice constant in Equation 1, a periodic structure with double-sided grooves of lattice constants d=0.5 mm, 1.0 mm, and 2.0 mm is chosen. For a step signal with a rise time of 30 ps, the minimum resolvable lattice constant is dₘᵢₙ=2.775 mm. Two weakly coupled subwavelength periodic structures (i.e., the first microstrip line 10 and the second microstrip line 20) are inserted between two signal lines H1 and H2 spaced three times the linewidth. The width w₁ of the first microstrip line 10 or the second microstrip line 20, which transmits low-frequency or DC signals, is 1.14 mm. The groove depth b is 0.342 mm, the spacing w₀ between the first microstrip line 10 and the second microstrip line 20 is 0.38 mm, and the spacing w₀ between the first microstrip line 10 or the second microstrip line 20 and the signal lines H1 or H2, which transmit high-speed signals, is also 0.38 mm. Here, the width w of the signal lines H1 and H2, which transmit high-speed signals, is chosen to be 1.14 mm, as this microstrip line width allows for good impedance matching with the SMA connector during the measurement process.

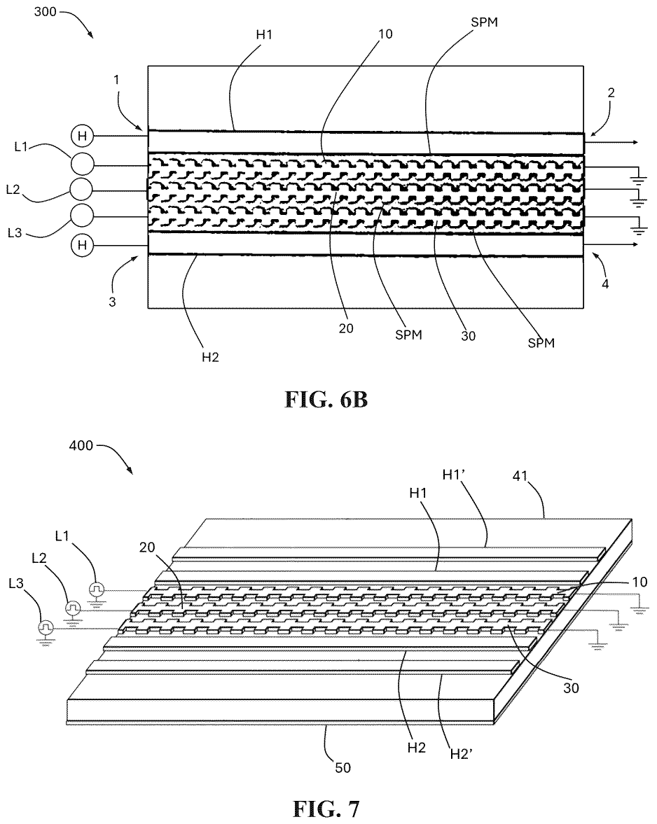

Referring to FIG. 6A, which illustrates a circuit transmission structure 200 of one embodiment, compared to circuit transmission structure 100, it further includes: a second microstrip line 20 disposed between the two signal lines H1 and H2, wherein an edge of the second microstrip line 20 is provided with a subwavelength periodic structure (SPM); and a second low-frequency or DC signal source L2 connected to one end of the second microstrip line 20. In detail, FIG. 6A illustrates an embodiment of circuit transmission structure 200 in which a first microstrip line 10 and a second microstrip line 20 for transmitting low-frequency signals are disposed between two high-speed signal lines H1 and H2. Both the first microstrip line 10 and the second microstrip line 20 are provided with staggered subwavelength periodic structures (SPM) at their edges.

Referring to FIG. 6B, FIG. 6B illustrates a circuit transmission structure 300 of one embodiment of the disclosure, which further includes, compared with circuit transmission structure 200: a third microstrip line 30 disposed between the two signal lines H1 and H2, wherein an edge of the third microstrip line 30 is provided with a subwavelength periodic structure SPM; and a third low-frequency or DC signal source L3 connected to one end of the third microstrip line 30.

In detail, please refer to FIGS. 4A to 4D, which illustrate the circuit transmission structures 110 to 310 of various embodiments disclosed herein and the variation of their parameter S_{dd41} with signal frequency. The signal lines transmitting high-frequency signals can be differential pairs, for example, signal lines H1 and H1′ forming a differential pair, and signal lines H2 and H2′ forming another differential pair. The disclosure is not limited to this. FIG. 4A illustrates a first microstrip line 10 disposed between two differential pairs. FIG. 4B illustrates a first microstrip line 10 and a second microstrip line 20 disposed between two differential pairs. FIG. 4C illustrates a first microstrip line 10, a second microstrip line 20, and a third microstrip line 30 disposed between two differential pairs. In detail, according to common knowledge in the art, when the distance between two differential pairs is maintained at 3 times the linewidth, the more microstrip lines inserted between the differential pairs, the closer the lines are to each other, and the worse the crosstalk should become. However, as shown in the experimental data in FIG. 4D, the circuit transmission structure disclosed in this disclosure actually shows a more significant reduction in crosstalk at high-frequency signals when more microstrip lines are inserted between the differential pairs. Therefore, it can provide higher density of circuit board trace and improve trace utilization.

Please refer to FIG. 7, which shows a partial perspective view of a circuit board 400 according to one embodiment of this disclosure. The circuit board 400 includes: a substrate 41, a first microstrip line 10, and a low-frequency or DC signal source L1. The first microstrip line 10 is disposed on the substrate 41 and between two signal lines H1 and H2 for transmitting high-frequency signals, wherein an edge of the first microstrip line 10 is provided with a subwavelength periodic structure. The low-frequency or DC signal source L1 is connected to one end of the first microstrip line 10. The distance between the two signal lines H1 and H2 is less than or equal to three times the linewidth of any one of the signal lines H1 or H2. In detail, the circuit board 400 can be a single-layer board or a multi-layer board. The high-frequency signal source (not shown) can be disposed on the substrate 41 or outside the substrate 41. The signal lines transmitting high-frequency signals can be a differential pair, for example, signal lines H1 and H1′ form a differential pair, and signal lines H2 and H2′ form another differential pair. This disclosure is not limited thereto.

Referring to FIG. 7, the circuit board 400 of one embodiment of this disclosure further includes: a second microstrip line 20 disposed on the substrate 41 and between the two signal lines H1 and H2, wherein at least one edge of the second microstrip line 20 is provided with a subwavelength periodic structure; and a second low-frequency or DC signal source L2 connected to one end of the second microstrip line 20.

Referring to FIG. 7, the circuit board 400 of one embodiment of this disclosure further includes: a third microstrip line 30 disposed on the substrate 41 and between the two signal lines H1 and H2, wherein at least one edge of the third microstrip line 30 is provided with a subwavelength periodic structure; and a third low-frequency or DC signal source L3 connected to one end of the third microstrip line 30.

In some embodiments of the disclosure, the circuit board 400 further includes the feature disclosure in any one of FIGS. 4A to 6B such as a load, a metal conductor, a matching resistor, or an open circuit of another end of the first microstrip line as the circuit transmission structure. For the sake of brevity, please refer to the above description for other features, which will not be repeated here.

Compared with the prior art, the first microstrip line disclosed herein is used to transmit low-frequency or DC signals and the edge of the first microstrip line is provided with the subwavelength periodic structure, so that even if the two signal lines are spaced less than or equal to three times the linewidth of any one of the two signal lines, there will not be too much crosstalk, and the transmission of low-frequency or DC signals on the first microstrip line will not be affected, thereby improving the utilization rate of traces on the circuit board and avoiding the issues in the prior art.

The above description is to illustrate the characteristics of the disclosure through preferred embodiments. The purpose is to enable those skilled in the art to understand the content of the disclosure and implement it accordingly, but not to limit the patent scope of the application. Therefore, any other equivalent modifications or modifications that do not depart from the technical ideas disclosed in the disclosure shall still be included in the claim scope described below.

What is claimed is:

1. A circuit transmission structure, comprising:
a first microstrip line disposed between two signal lines for transmitting high-frequency signals, wherein an edge of the first microstrip line is provided with a subwavelength periodic structure; and
a low-frequency or DC signal source connected to one end of the first microstrip line.

2. The circuit transmission structure of claim 1, wherein the two signal lines are spaced at a distance less than or equal to three times a linewidth of one of the two signal lines.

3. The circuit transmission structure of claim 2, further comprising:
a second microstrip line disposed between the two signal lines, wherein an edge of the second microstrip line is provided with a subwavelength periodic structure; and
a second low-frequency or DC signal source connected to one end of the second microstrip line.

4. The circuit transmission structure of claim 3, further comprising:
a third microstrip line disposed between the two signal lines, wherein an edge of the third microstrip line is provided with a subwavelength periodic structure; and
a third low-frequency or DC signal source connected to one end of the third microstrip line.

5. The circuit transmission structure of claim 1, further comprising a load electrically connected to another end of the first microstrip line.

6. The circuit transmission structure of claim 1, further comprising a matching resistor electrically connected to another end of the first microstrip line.

7. The circuit transmission structure of claim 6, wherein a resistance value of the matching resistor is between 48.75Ω and 101.25Ω.

8. The circuit transmission structure of claim 1, further comprising a metal conductor electrically connected between another end of the first microstrip line and a current return path.

9. The circuit transmission structure of claim 1, wherein another end of the first microstrip line is an open circuit.

10. The circuit transmission structure of claim 1, wherein a period constant of the subwavelength periodic structure is less than dₘᵢₙ, where
$${d}_{min} = \frac{v {R}_{T}}{2} ,$$
v is a propagation rate of electromagnetic wave of the low-frequency or DC signal source in the first microstrip line, and R_{T} is a rise time of digital signal.

11. A circuit board, comprising:
a substrate;
a first microstrip line disposed on the substrate and between two signal lines for transmitting high-frequency signals, wherein an edge of the first microstrip line is provided with a subwavelength periodic structure; and
a low-frequency or DC signal source connected to one end of the first microstrip line, wherein a distance between the two signal lines is less than or equal to three times a linewidth of any one of the two signal lines.

12. The circuit board of claim 11, further comprises:
a second microstrip line disposed on the substrate and between the two signal lines, wherein an edge of the second microstrip line is provided with a subwavelength periodic structure; and
a second low-frequency or DC signal source connected to one end of the second microstrip line.

13. The circuit board of claim 12, further comprises:
a third microstrip line disposed on the substrate and between the two signal lines, wherein an edge of the third microstrip line is provided with a subwavelength periodic structure; and
a third low-frequency or DC signal source connected to one end of the third microstrip line.

14. The circuit board of claim 11, further comprising a load electrically connected to another end of the first microstrip line.

15. The circuit board of claim 11, further comprising a matching resistor electrically connected to another end of the first microstrip line.

16. The circuit board of claim 15, wherein a resistance value of the matching resistor is between 48.75Ω and 101.2Ω.

17. The circuit board of claim 11, further comprising a metal conductor electrically connected between another end of the first microstrip line and a current return path.

18. The circuit board of claim 11, wherein another end of the first microstrip line is an open circuit.

19. The circuit board of claim 11, wherein a period constant of the subwavelength periodic structure is less than dₘᵢₙ, where
$${d}_{min} = \frac{v {R}_{T}}{2} ,$$
v is a propagation rate of electromagnetic wave of the low-frequency or DC signal source in the first microstrip line, and R_{T} is a rise time of digital signal.
